(19) United States
(12) Patent Application Publication
(10) Pub. No.: US 2025/0183124 A1
(43) Pub. Date: Jun. 5, 2025

(54) MICROELECTRONIC PACKAGE WITH RAISED CONNECTOR FOR EXTERNAL COMPONENT

(71) Applicant: Texas Instruments Incorporated, Dallas, TX (US)

(72) Inventors: John Carlo C Molina, Limay (PH); Charmaine Grace Facal, Olongapo City (PH); Lorraine D Quijano, Angeles (PH)

(21) Appl. No.: 18/524,264

(22) Filed: Nov. 30, 2023

(51) Int. Cl. H01L 23/495; H01L 23/00; H01L 25/065

(52) U.S. Cl. CPC H01L 23/4951; H01L 23/49565; H01L 23/49575; H01L 24/08; H01L 24/40; H01L 25/0652; H01L 2224/08145; H01L 2224/08155; H01L 2224/40139; H01L 2224/40145; H01L 2924/01029; H01L 2924/01079; H01L 2924/014; H01L 2924/182

(57) ABSTRACT

A semiconductor package is configured for electrically connecting an external component to a top surface of the semiconductor package. The semiconductor package includes a raised connector that extends from a lead frame portion, vertically through encapsulation material, and is exposed at the top surface. A semiconductor component is electrically connected to the lead frame portion. The raised connector includes a vertical column and a horizontal pad, contiguous with each other. The raised connector has a continuous core, which is electrically conductive, extending throughout the vertical column and throughout the horizontal pad. The vertical column is attached to the lead frame portion. A top surface of the horizontal pad is exposed at a top surface of the encapsulation material. The raised connector may include two or more vertical columns. The semiconductor package may include two or more raised connectors, each attached to the lead frame portion.

### TECHNICAL FIELD

This disclosure relates to the field of microelectronic devices. More particularly, but not exclusively, this disclosure relates to connectors in microelectronic devices for connections to external components.

### BACKGROUND

Semiconductor packages are widely used in the electronics industry to house and protect semiconductor components such as integrated circuits (ICs) and other microelectronic components. These packages provide a means to connect the semiconductor component to external circuitry and protect the semiconductor component from environmental factors such as moisture, dust, and physical damage. Semiconductor packages are frequently connected to external components, enhancing functionality, performance, and miniaturization. As electronic devices continue to become smaller and more powerful, there is a growing demand for semiconductor packages that provide integration with external components, such as passive components, to create more compact and versatile electronic systems.

### SUMMARY

A semiconductor package includes a portion of a lead frame portion (lead frame portion) and a semiconductor component electrically connected to the lead frame portion. The semiconductor package also includes an encapsulation material contacting the lead frame portion. The semiconductor package further includes a raised connector extending from the lead frame portion vertically through the encapsulation material. The raised connector includes a vertical column and a horizontal pad contiguous with the vertical column. The raised connector has a continuous core extending throughout the vertical column and throughout the horizontal pad. The continuous core is electrically conductive. The vertical column is attached to the lead frame portion. The horizontal pad is exposed at a top surface of the encapsulation material.

### BRIEF DESCRIPTION OF THE VIEWS OF THE DRAWINGS

FIG. 1A through FIG. 1H are perspective views and a cross-section of a semiconductor package having a raised connector.

FIG. 2A and FIG. 2B are perspective views of another example semiconductor package having raised connectors.

FIG. 3A through FIG. 3F are perspective views of a semiconductor package having a raised connector.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

A semiconductor package includes a lead frame portion having leads extending to an exterior of the package. The leads are suitable for attaching and electrically connecting the semiconductor package to a circuit board or other external connection structure. The semiconductor package includes a semiconductor component electrically connected to the lead frame portion. The semiconductor package also includes an encapsulation material contacting the lead frame portion. The encapsulation material is electrically non-conductive.

The semiconductor package further includes a raised connector that is electrically conductive, extending from the lead frame portion vertically through the encapsulation material. The raised connector includes a vertical column and a horizontal pad contiguous with the vertical column. The raised connector has a continuous core extending throughout the vertical column and throughout the horizontal pad. The continuous core is electrically conductive. The vertical column is attached to the lead frame portion, and makes an electrical connection to a lead of the lead frame portion. The horizontal pad is exposed at a top surface of the encapsulation material, opposite from the lead frame portion. The continuous core may provide lower electrical resistance between the lead frame portion and an exposed portion of the horizontal pad, compared to a connection structure having a plurality of elements with interfaces such as solder joints between the elements. The continuous core may thus provide increased performance and reliability for the semiconductor package.

In some versions of the semiconductor package, the raised connector may have solderable material on the exposed portion of the horizontal pad. In other versions of the semiconductor package, the raised connector may have solderable material covering the continuous core.

In some versions of the semiconductor package, the raised connector may have two or more vertical columns. Some versions of the semiconductor package may include two or more raised connectors.

An external component may be attached to the semiconductor package at the top surface of the encapsulation material, with an electrical connection between a terminal of the external component and the exposed portion of the horizontal pad. Having the external component electrically connected to the lead frame portion through the raised connector may reduce electrical resistance, inductance, and/or capacitance between the semiconductor component and the external component, advantageously improving performance of a circuit containing the semiconductor component and the external component. Having the external component attached to the semiconductor package at the top surface of the encapsulation material may advantageously reduce an area of the circuit board or other external connection structure that is taken up by a combination of the semiconductor package and the external component.

As used in the present description, when an electrically conductive structure is described as being “exposed at” a surface of another element that is electrically non-conductive, it indicates that the electrically conductive structure is available for electrical contact from outside the dielectric structure. Thus, the conductive structure that is exposed at the surface of the electrically non-conductive element may project from the surface; may be flush with the surface; or may be recessed relative to the surface while being exposed.

The terms “vertical” and “vertically” refer to directions perpendicular to the top surface of the semiconductor package. The term “horizontal” refers to directions parallel to the top surface of the semiconductor package.

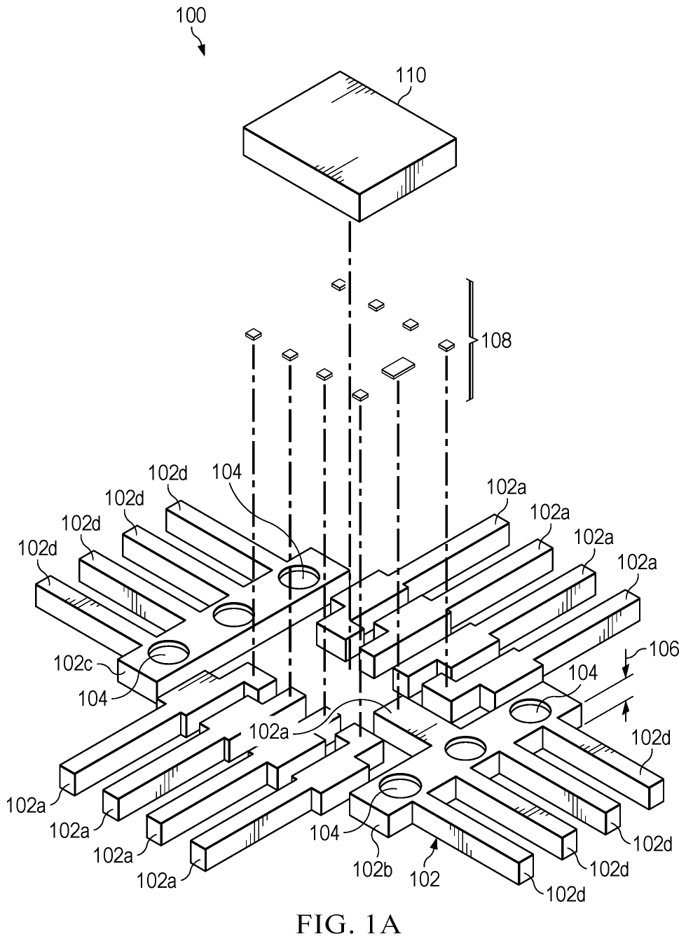

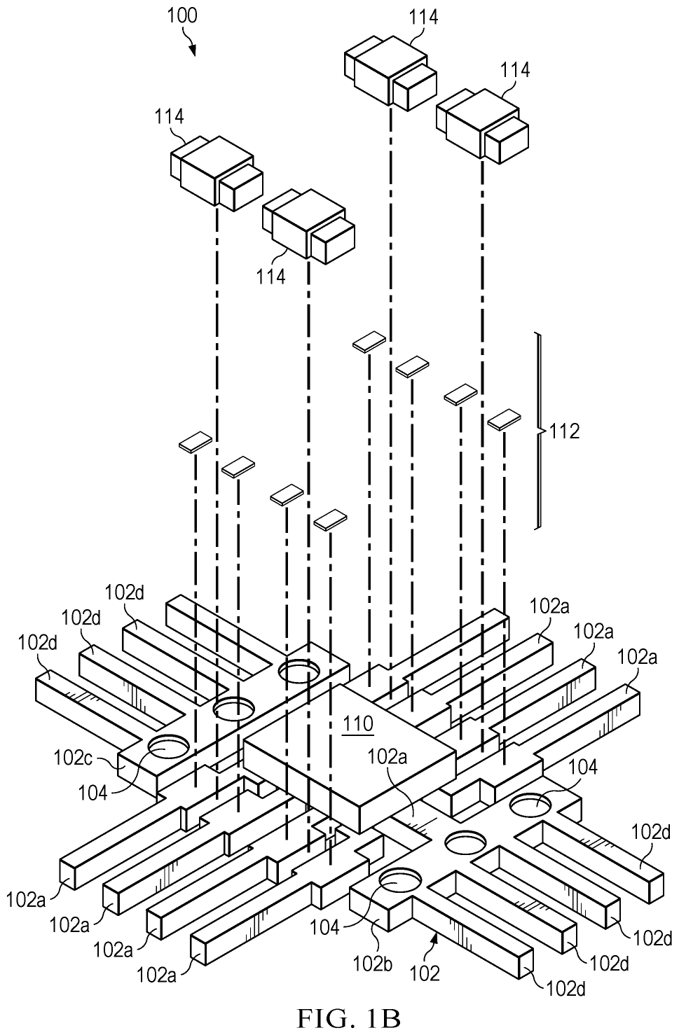

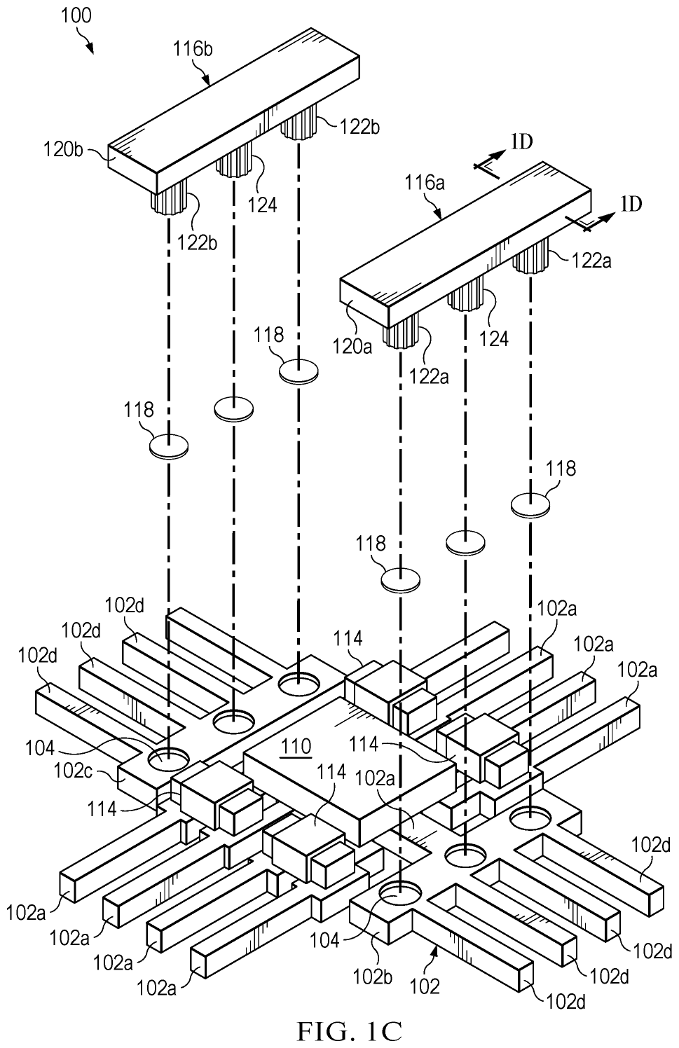

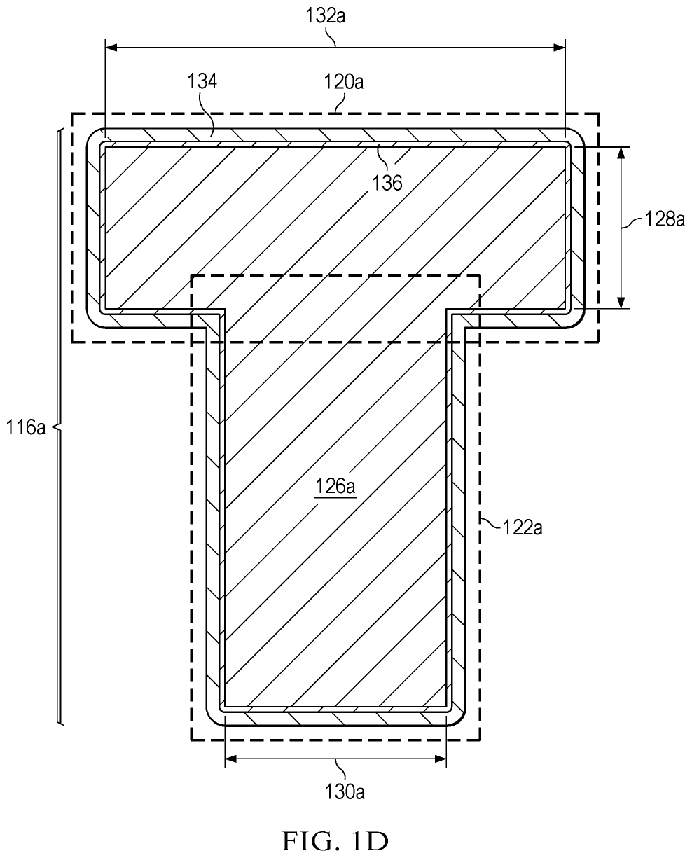

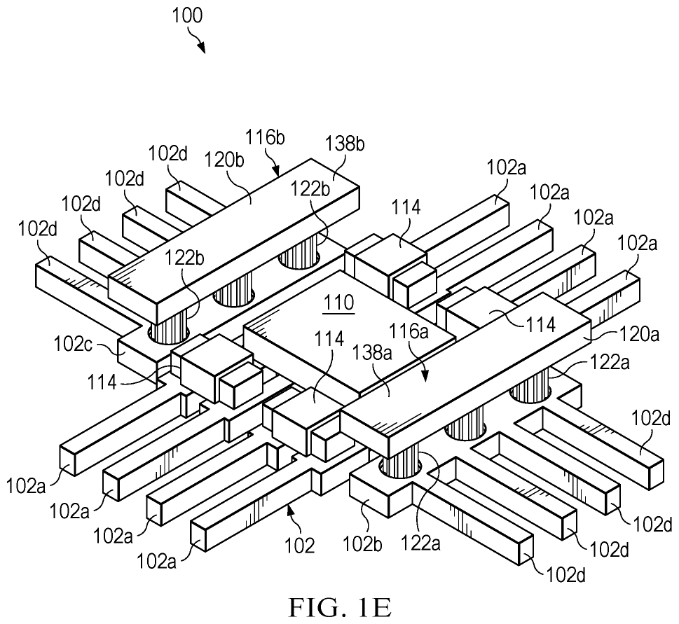

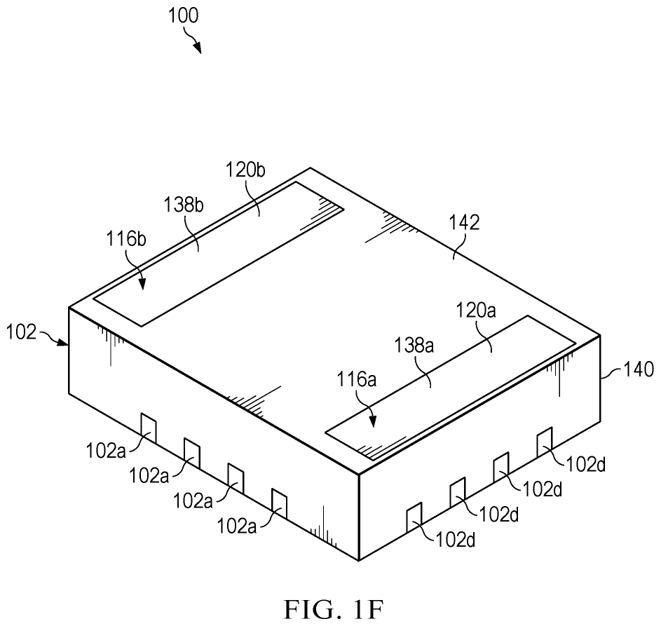

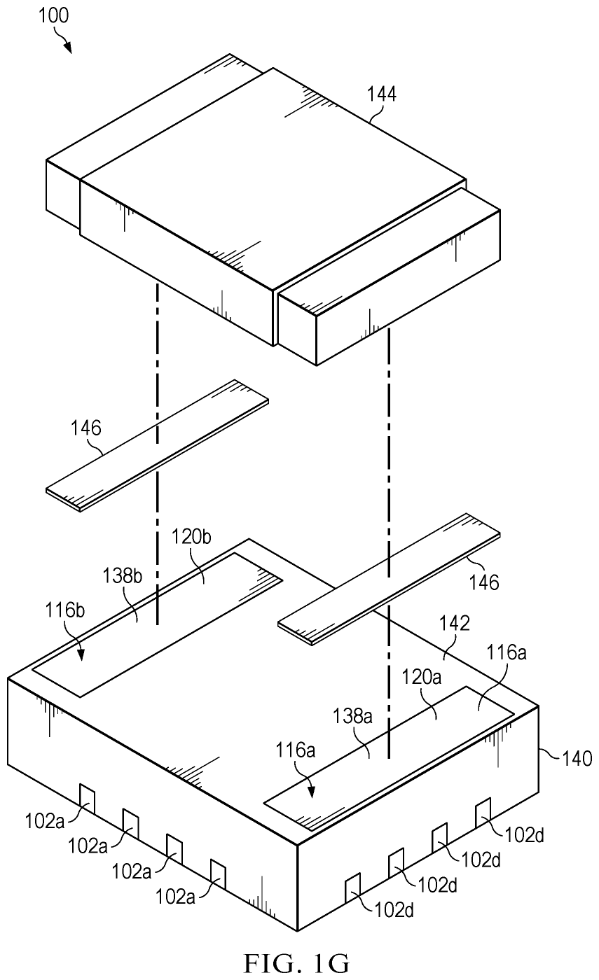

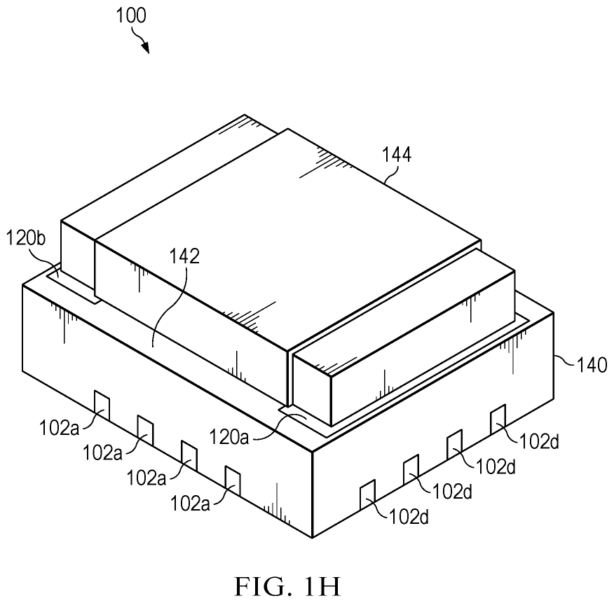

FIG. 1A through FIG. 1H are perspective views and a cross-section of a semiconductor package having a raised connector. Referring to FIG. 1A, the semiconductor package 100 includes a lead frame portion 102 of a lead frame. The lead frame portion 102 is electrically conductive. The lead frame portion 102 may include primarily copper or alloy 42, by way of example. The alloy 42 may be flashed with nickel and plated with gold to reduce corrosion and improve reliability of the semiconductor package 100. The lead frame portion 102 includes leads 102a, used to provide power and carry signals. The leads 102a extend to structural elements, not shown, of the lead frame portion 102, such as dam bars. The lead frame portion 102 may be part of a lead frame that includes positions for additional semiconductor packages, not shown. The lead frame portion 102 of this example includes a first component bus 102b and a second component bus 102c. The lead frame portion 102 further includes struts 102d extending from the first component bus 102b and the second component bus 102c to the structural elements of the lead frame portion 102, which hold the first component bus 102b and the second component bus 102c in position during assembly of the semiconductor package 100. The first component bus 102b and the second component bus 102c of this example have alignment structures 104 to facilitate positioning first vertical columns 122a and second vertical columns 122b, shown in FIG. 1C, on the first component bus 102b and the second component bus 102c. Still referring to FIG. 1A, in this example, the alignment structures 104 may be implemented as recesses 104. The lead frame portion 102 has a bus thickness 106 adjacent to the recesses 104. The bus thickness 106 may be 250 microns to 2 millimeters, by way of example.

First electrical connections 108 of the semiconductor package 100 are formed on the lead frame portion 102 to electrically connect a semiconductor component 110 of the semiconductor package 100 to the leads 102a. The first electrical connections 108 may be implemented as solder joints, formed by a ball drop operation, by a solder paste dispensing operation, or by placing solder preforms on the leads 102a, followed by a solder reflow process. Other methods of forming the first electrical connections 108, such as forming gold bumps or copper bumps, or copper hybrid bonding, are within the scope of this example.

The semiconductor component 110 may be implemented as an integrated circuit or a discrete transistor, by way of example. The semiconductor component 110 may be formed in silicon, silicon carbide, gallium nitride, or other semiconductor material.

Referring to FIG. 1B, second electrical connections 112 of the semiconductor package 100 are formed on the lead frame portion 102 to electrically connect internal components 114 to the leads 102a. The second electrical connections 112 may be implemented similarly to the first electrical connections 108 of FIG. 1A, or by another method. The internal components 114 may be implemented as capacitors, resistors, and/or diodes, by way of example.

Referring to FIG. 1C, a first raised connector 116a is electrically connected to the first component bus 102b by instances of third electrical connections 118, and a second raised connector 116b is electrically connected to the second component bus 102c by additional instances of the third electrical connections 118. The third electrical connections 118 may be implemented as solder joints, formed by a ball drop process, or may be implemented as other electrical connective structure and formed by other methods. The first raised connector 116a may be positioned on the first component bus 102b, and the second raised connector 116b may be positioned on the second component bus 102c by a pick and place operation, by way of example.

The first raised connector 116a includes a first horizontal pad 120a and includes first vertical columns 122a contiguous with the first horizontal pad 120a. The second raised connector 116b includes a second horizontal pad 120b and includes second vertical columns 122b contiguous with the second horizontal pad 120b. In this example, the first vertical columns 122a fit into the recesses 104 in the first component bus 102b, and the second vertical columns 122b fit into the recesses 104 in the second component bus 102c, which may advantageously facilitate placement of the first raised connector 116a and the second raised connector 116b on the lead frame portion 102. The first vertical columns 122a and the second vertical columns 122b may have textured surfaces 124 which may contact a subsequently formed encapsulation material 140, shown in FIG. 1F and advantageously improve adhesion to the encapsulation material 140. The textured surfaces 124 may be implemented as vertical grooves, as depicted in FIG. 1C, or by other textures, such as roughened surfaces, horizontal grooves, spiral grooves, or pits. The first raised connector 116a and the second raised connector 116b may be manufactured by stamping, electroplating, additive manufacturing, or a combination thereof.

FIG. 1D is a cross section of the first raised connector 116a. The first raised connector 116a has a first continuous core 126a that is electrically conductive. The first continuous core 126a extends throughout the first vertical columns 122a and the first horizontal pad 120a, which may reduce electrical resistance of the first raised connector 116a compared to connectors of two or more pieces having interfaces between the pieces, advantageously providing improved performance and reliability for the first raised connector 116a. The first continuous core 126a may include primarily copper, by way of example.

A first pad thickness 128a of the first continuous core 126a in the first horizontal pad 120a may be greater than the bus thickness 106, shown in FIG. 1A, of the lead frame portion 102, which may further reduce electrical resistance of the first raised connector 116a compared to a connector having a thinner horizontal pad, further advantageously improving performance and reliability. The first pad thickness 128a may be 300 microns to 3 millimeters, by way of example.

A first column width 130a of the first continuous core 126a in the first vertical columns 122a may be greater than the bus thickness 106, shown in FIG. 1A, of the lead frame portion 102, which may further reduce electrical resistance of the first raised connector 116a compared to a connector having more narrow columns, further advantageously improving performance and reliability. The first column width 130a may be 400 microns to 3 millimeters, by way of example.

A first pad width 132a of the first continuous core 126a in the first horizontal pad 120a may be greater than the first column width 130a, which may advantageously provide more connection area for an external component, such as an external component 144 shown in FIG. 1G and FIG. 1H. The first pad width 132a may be 500 microns to 4 millimeters, by way of example.

The first raised connector 116a may include a solderable material 134 surrounding the first continuous core 126a. The solderable material 134 may include solder, gold, or silver, by way of example. The solderable material 134 may be 10 microns to 100 microns thick, by way of example. The first raised connector 116a may include a diffusion barrier 136 between the solderable material 134 and the first continuous core 126a. The diffusion barrier 136 may include nickel, for example, which may advantageously reduce formation of intermetallic compounds of copper from the first continuous core 126a and tin in the solderable material 134. The diffusion barrier 136 may be 5 microns to 50 microns thick, by way of example.

FIG. 1E depicts the semiconductor package 100 after the first raised connector 116a and the second raised connector 116b are attached to the lead frame portion 102. A first top surface 138a of the first horizontal pad 120a extends above the semiconductor component 110 and the internal components 114. Similarly, a second top surface 138b of the second horizontal pad 120b extends above the semiconductor component 110 and the internal components 114. The first top surface 138a and the second top surface 138b are substantially coplanar.

Referring to FIG. 1F, an encapsulation material 140 of the semiconductor package 100 is formed on the lead frame portion 102, the semiconductor component 110 of FIG. 1E, the internal components 114 of FIG. 1E, and the first vertical columns 122a and the second vertical columns 122b of FIG. 1E. The first top surface 138a of the first horizontal pad 120a and the second top surface 138b of the second horizontal pad 120b are exposed at a top surface 142 of the encapsulation material 140, that is, the encapsulation material 140 does not cover the first top surface 138a and the second top surface 138b. In some versions of this example, the encapsulation material 140 may extend partway onto the first top surface 138a and the second top surface 138b. The encapsulation material 140 is electrically non-conductive, and may include epoxy with inorganic filler particles, by way of example. The encapsulation material 140 may be formed by a film assisted molding process to reduce extrusion of the encapsulation material 140 onto the first top surface 138a and the second top surface 138b.

After the encapsulation material 140 is formed, the leads 102a and the struts 102d are trimmed to separate the semiconductor package 100 from the rest of the lead frame portion 102. The leads 102a and the struts 102d may be trimmed by a saw singulation process, leaving ends of the leads 102a and the struts 102d flush with sides of the encapsulation material 140, as depicted in FIG. 1F. Alternatively, the leads 102a and the struts 102d may be trimmed by a punch process. The first top surface 138a and the second top surface 138b are suitable for forming electrical connections to an external component. The semiconductor package 100 as shown in FIG. 1F is suitable for user applications in which the semiconductor package 100 is attached to a circuit board, and an external component is subsequently electrically connected to the first top surface 138a and the second top surface 138b. Alternatively, the semiconductor package 100 may include an external component 144, shown in FIG. 1G, which is electrically connected to the first top surface 138a and the second top surface 138b prior to providing the semiconductor package 100 for attachment to a circuit board.

Referring to FIG. 1G, external electrical connections 146 are formed between the external component 144 and the first horizontal pad 120a and the second horizontal pad 120b. The external component 144 may be implemented as an inductor or a capacitor, by way of example. Other implementations for the external component 144 are within the scope of this example. The external electrical connections 146 may be solder joints, formed by applying solder paste or solder preforms to the first top surface 138a of the first horizontal pad 120a and the second top surface 138b of the second horizontal pad 120b, followed by a solder reflow process with the external component 144 in place. Alternatively, the external electrical connections 146 may be formed using electrically conductive adhesive, such as epoxy with metal particles. Other implementations of the external electrical connections 146 are within the scope of this example. The external component 144 may also be attached to the top surface 142 of the encapsulation material 140, separately from the external electrical connections 146, using an electrically non-conductive adhesive.

FIG. 1H depicts the semiconductor package 100 after the external component 144 is electrically connected to the first horizontal pad 120a and the second horizontal pad 120b. Having the first horizontal pad 120a and the second horizontal pad 120b exposed by the encapsulation material 140 at the top surface 142 may advantageously enable use of surface mount technology (SMT) configurations of the external component 144, without need for additional clips or leads to match dimensions of the semiconductor package 100. The first horizontal pad 120a and the second horizontal pad 120b may advantageously accommodate a variety of sizes for the external component 144.

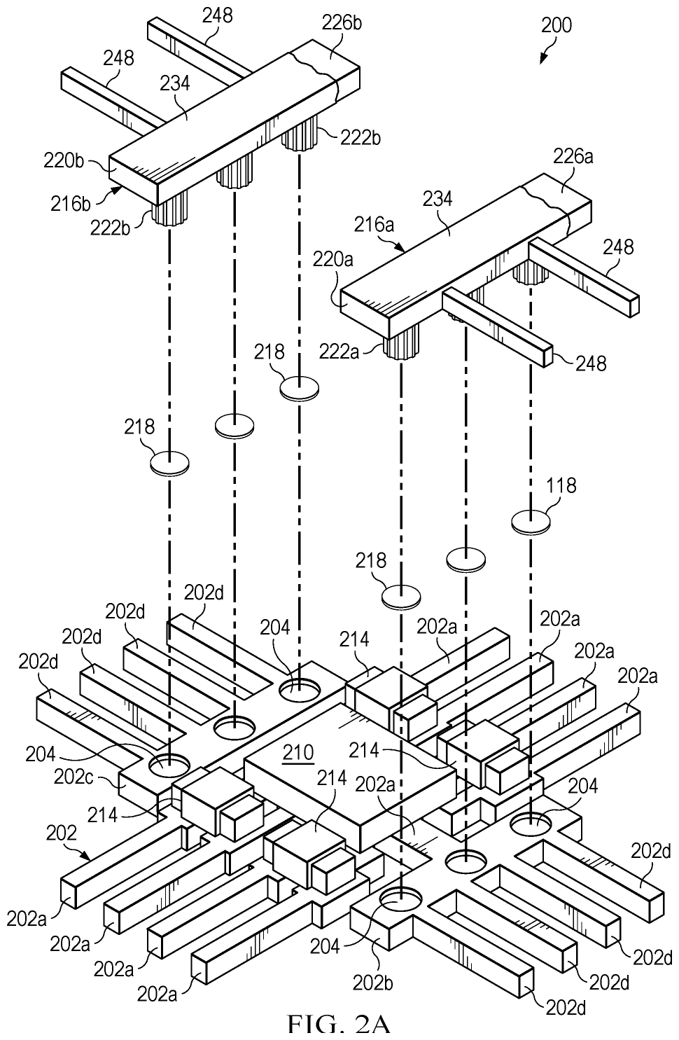

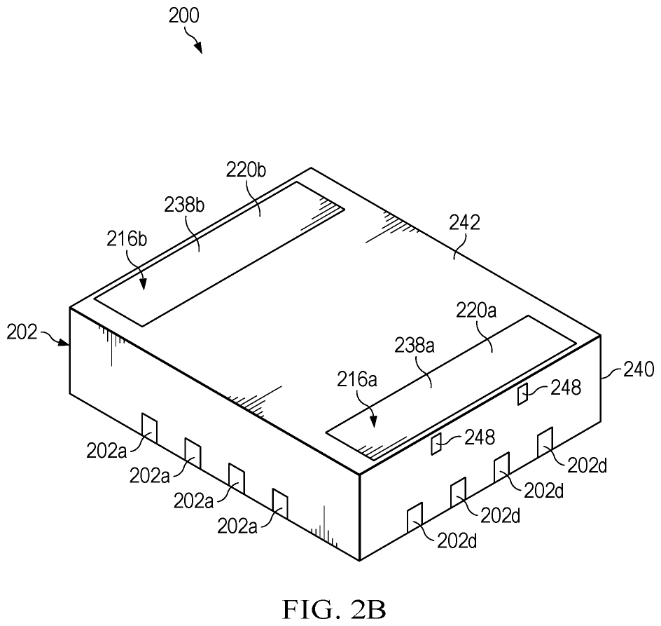

FIG. 2A and FIG. 2B are perspective views of another example semiconductor package having raised connectors. Referring to FIG. 2A, the semiconductor package 200 includes a first lead frame portion 202 of a lead frame, which may be similar to the lead frame portion 102 of FIG. 1A. The first lead frame portion 202 includes leads 202a, a first component bus 202b and a second component bus 202c. The first lead frame portion 202 further includes first struts 202d extending from the first component bus 202b and the second component bus 202c The first component bus 202b and the second component bus 202c of this example have recesses 204 to facilitate attachment of first vertical columns 222a and second vertical columns 222b.

A semiconductor component 210 of the semiconductor package 200 is electrically connected to the leads 202a. Internal components 214 are electrically connected to the leads 202a.

A first raised connector 216a includes a first horizontal pad 220a and includes first vertical columns 222a contiguous with the first horizontal pad 220a. The first raised connector 216a has a first continuous core 226a extending throughout the first vertical columns 222a and with the first horizontal pad 220a. The first raised connector 216a of this example includes instances of second struts 248 extending from the first horizontal pad 220a to a second lead frame portion of the lead frame, not shown, to facilitate positioning the first raised connector 216a during formation of the semiconductor package 200. The first raised connector 216a includes a solderable material 234 surrounding the first continuous core 226a.

A second raised connector 216b has a structure similar to the first raised connector 216a, with a second continuous core 226b extending throughout a second horizontal pad 220b and second vertical columns 222b contiguous with the first horizontal pad 220a. The second raised connector 216b of this example includes additional instances of the second struts 248 extending from the second horizontal pad 220b to the second lead frame portion, not shown, to facilitate positioning the second raised connector 216b. The second raised connector 216b includes the solderable material 234 surrounding the second continuous core 226b.

The first raised connector 216a is electrically connected to the first component bus 202b by instances of electrical connections 218, and the second raised connector 216b is electrically connected to the second component bus 202c by additional instances of the electrical connections 218. The second struts 248 may advantageously hold the first raised connector 216a and the second raised connector 216b in position while the electrical connections 218 are formed.

Referring to FIG. 2B, an encapsulation material 240, which is electrically non-conductive, is formed on the first lead frame portion 202, the semiconductor component 210 of FIG. 2A, the internal components 214 of FIG. 2A, the first vertical columns 222a and the second vertical columns 222b of FIG. 2A, and the second struts 248. The first top surface 238a of the first horizontal pad 220a and the second top surface 238b of the second horizontal pad 220b are exposed at a top surface 242 of the encapsulation material 240.

After the encapsulation material 240 is formed, the leads 202a, the first struts 202d, and the second struts 248 are trimmed by a saw singulation process to separate the semiconductor package 200 from the rest of the first lead frame portion 202 and from the second lead frame portion. The saw singulation process leaves ends of the leads 202a, the first struts 202d, and the second struts 248 flush with sides of the encapsulation material 240, as depicted in FIG. 2B.

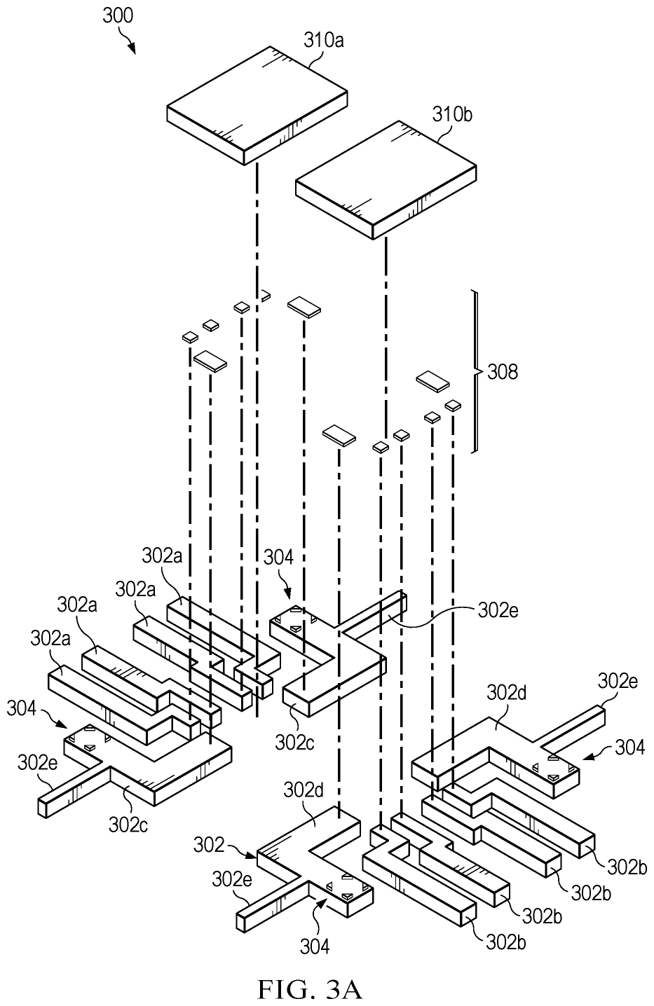

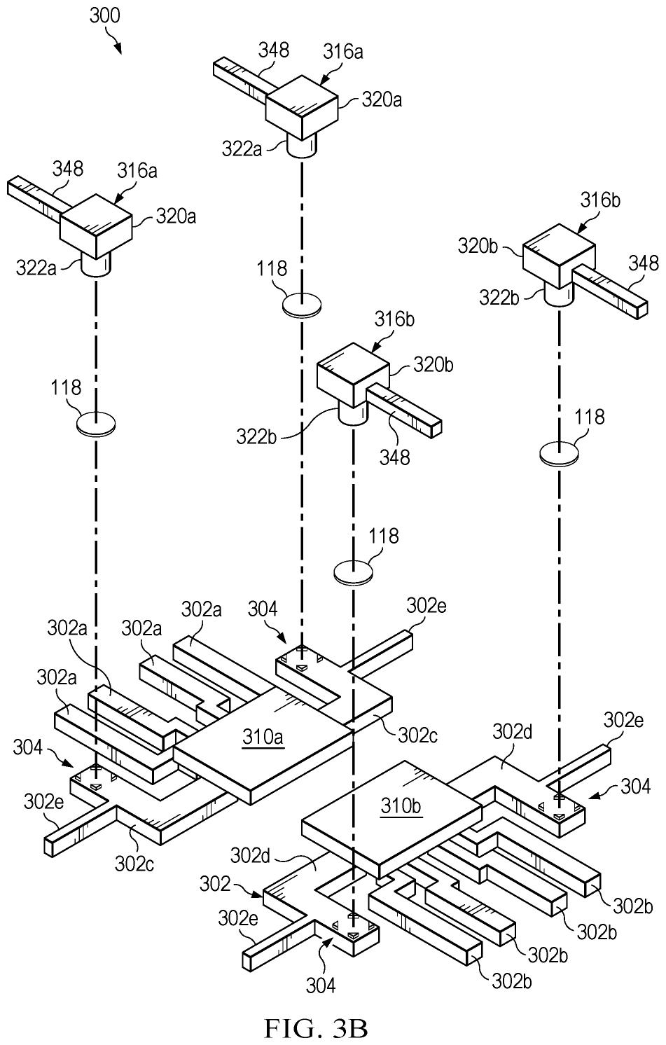

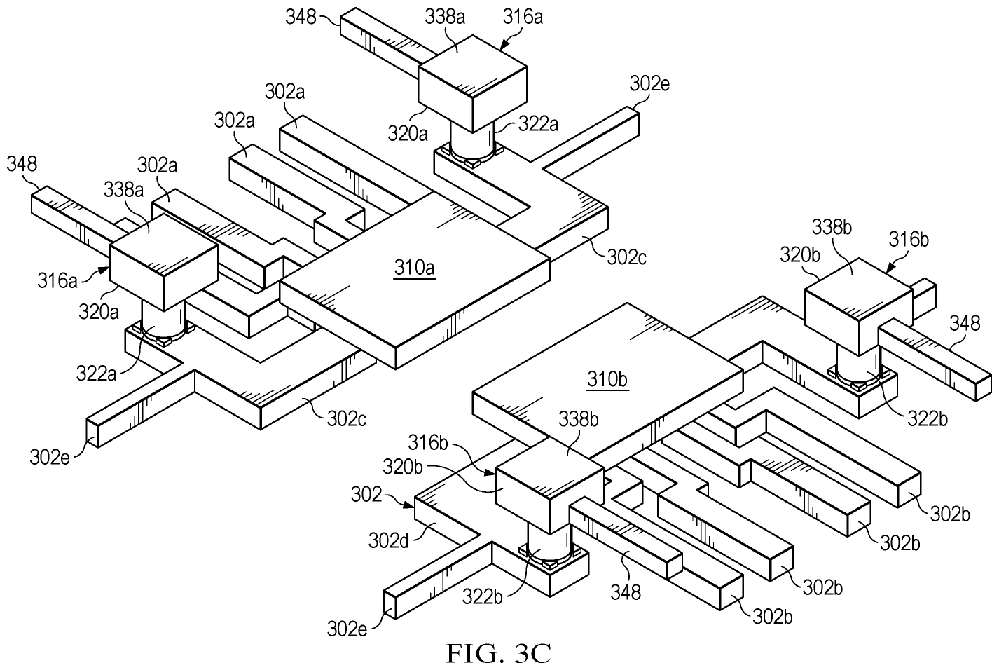

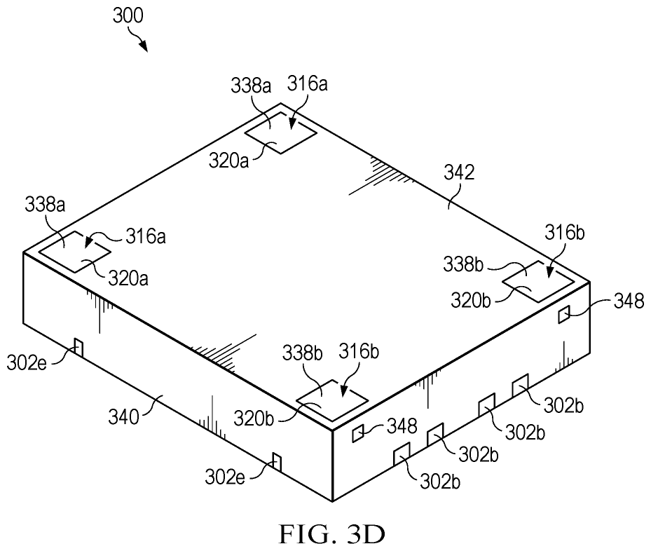

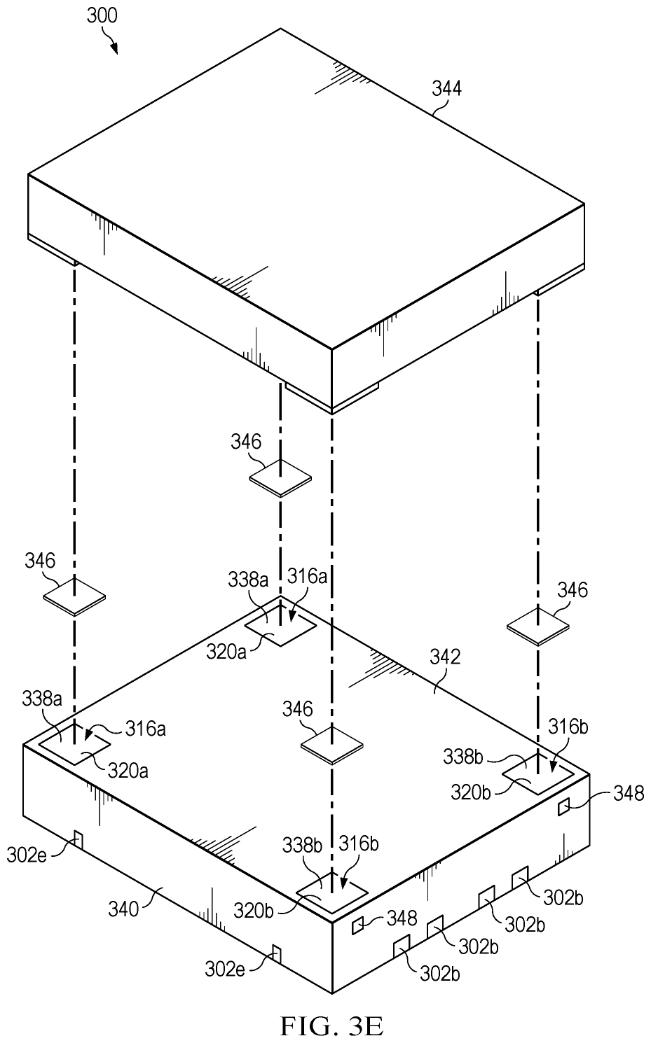

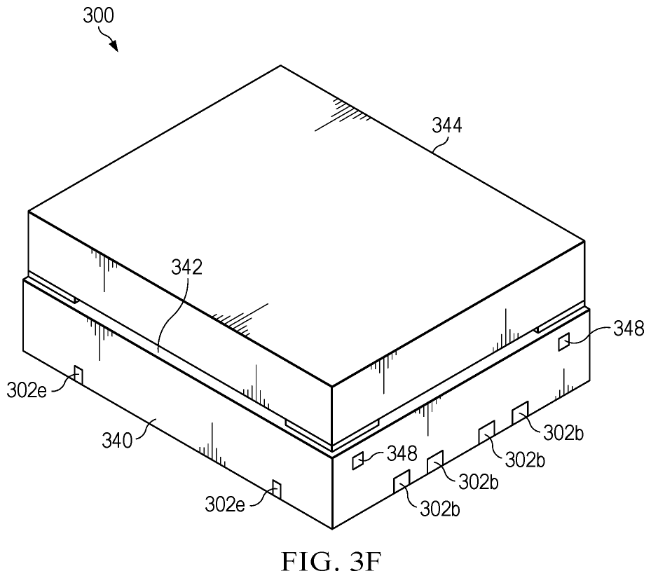

FIG. 3A through FIG. 3F are perspective views of a semiconductor package having a raised connector. Referring to FIG. 3A, the semiconductor package 300 includes a first lead frame portion 302 of a lead frame, which is electrically conductive. The first lead frame portion 302 of this example includes primary leads 302a to provide power and carry signals for a primary side of an isolation circuit, and secondary leads 302b to provide power and carry signals for a secondary side of the isolation circuit. The first lead frame portion 302 also includes primary transformer buses 302c to connect to a primary side of an external transformer 344, shown in FIG. 3E and FIG. 3F. The first lead frame portion 302 further includes secondary transformer buses 302d to connect to a secondary side of the external transformer 344. The first lead frame portion 302 includes first struts 302e extending from the primary transformer buses 302c and the secondary transformer buses 302d, which hold the primary transformer buses 302c and the secondary transformer buses 302d in position during assembly of the semiconductor package 300.

The primary transformer buses 302c and the secondary transformer buses 302d may have alignment structures 304 to facilitate placement of primary vertical columns 322a and secondary vertical columns 322b, shown in FIG. 3B, on the primary transformer buses 302c and the secondary transformer buses 302d. Still referring to FIG. 3A, in this example, the alignment structures 304 may be implemented as raised projections 304 extending from the primary transformer buses 302c and the secondary transformer buses 302d.

First electrical connections 308 of the semiconductor package 300 are formed on the first lead frame portion 302 to electrically connect a primary semiconductor component 310a to the primary leads 302a, and to electrically connect a secondary semiconductor component 310b to the secondary leads 302b. The first electrical connections 308 may be implemented as solder joints, by way of example.

Referring to FIG. 3B, primary raised connectors 316a are electrically connected to the primary transformer buses 302c by instances of second electrical connections 318, and secondary raised connectors 316b are electrically connected to the secondary transformer buses 302d by additional instances of the second electrical connections 318. The second electrical connections 318 may be implemented as solder joints, or may be implemented as other electrical connective structure and formed by other methods.

Each of the primary raised connectors 316a includes a primary horizontal pad 320a and includes a primary vertical column 322a contiguous with the primary horizontal pad 320a. Each of the secondary raised connectors 316b includes a secondary horizontal pad 320b and includes a secondary vertical column 322b contiguous with the secondary horizontal pad 320b. In this example, the primary vertical columns 322a fit between the raised projections 304 in the primary transformer buses 302c, and the secondary vertical columns 322b fit into the raised projections 304 in the secondary transformer buses 302d, which may advantageously facilitate placement of the primary raised connectors 316a and the secondary raised connectors 316b on the first lead frame portion 302.

The primary raised connectors 316a include instances of second struts 348 extending from the primary horizontal pads 320a to a second lead frame portion, not shown. Similarly, the secondary raised connectors 316b include additional instances of the second struts 348 extending from the secondary horizontal pads 320b to the second lead frame portion. The second struts 348 may advantageously hold the primary raised connectors 316a and the secondary raised connectors 316b in position while the primary raised connectors 316a and the secondary raised connectors 316b are attached to the lead frame portion 302.

FIG. 3C depicts the semiconductor package 300 after the second electrical connections 318 are formed between the first lead frame portion 302 and the primary raised connectors 316a and the secondary raised connectors 316b. Primary top surfaces 338a of the primary horizontal pads 320a and secondary top surfaces 338b of the secondary horizontal pads 320b extend above the semiconductor components 310a and 310b. The primary top surfaces 338a and the secondary top surfaces 338b are substantially coplanar.

Referring to FIG. 3D, an encapsulation material 340 is formed on the first lead frame portion 302, the semiconductor components 310a and 310b of FIG. 3C, and the primary vertical columns 322a and the secondary vertical columns 322b of FIG. 3C. The primary top surfaces 338a of the primary horizontal pads 320a and the secondary top surfaces 338b of the secondary horizontal pads 320b are exposed at a top surface 342 of the encapsulation material 340. The encapsulation material 340 is electrically non-conductive.

After the encapsulation material 340 is formed, the primary leads 302a of FIG. 3C, the secondary leads 302b, the first struts 302e, and the second struts 348 are trimmed by a saw singulation process, leaving ends of the primary leads 302a, the secondary leads 302b, the first struts 302e, and the second struts 348 flush with sides of the encapsulation material 340, as depicted in FIG. 3D. The semiconductor package 300 as shown in FIG. 3D is suitable for applications in which an external component is subsequently electrically connected to the primary top surfaces 338a and the secondary top surfaces 338b.

Referring to FIG. 3E, the semiconductor package 300 may include an external component 344, which is electrically connected to the primary top surfaces 338a and the secondary top surfaces 338b. In this example, the external component 344 may be implemented as an external transformer 344. Other implementations for the external component 344 are within the scope of this example.

External electrical connections 346 are formed between the external transformer 344 and the primary horizontal pads 320a and the secondary horizontal pads 320b. The external electrical connections 346 may be solder joints, or other implementations.

FIG. 3F depicts the semiconductor package 300 after the external transformer 344 is electrically connected to the primary horizontal pads 320a and the secondary horizontal pads 320b of FIG. 3E. Having the primary horizontal pads 320a and the secondary horizontal pads 320b exposed by the encapsulation material 340 at the top surface 342 may advantageously enable use of SMT versions of the external transformer 344. The primary horizontal pads 320a and the secondary horizontal pads 320b may advantageously accommodate a variety of sizes for the external transformer 344.

Various features of the examples disclosed herein may be combined in other manifestations of example semiconductor packages. For example, the raised connectors 116a and 116b of FIG. 1C may have second struts, similar to second struts 248 extending from the raised connectors 216a and 216b of FIG. 2A. The first lead frame portion 302 of FIG. 3A may have recesses, similar to the recesses 104 of FIG. 1A, for the primary vertical columns 322a and the secondary vertical columns 322b, in addition to, or instead of, the raised projections 304. The lead frame portions 102 and 202 of FIG. 1A and FIG. 1B, respectively, may have raised projections, similar to the raised projections 304 of FIG. 3A. The primary vertical columns 322a and the secondary vertical columns 322b of FIG. 3A may have textured surfaces, similar to the textured surfaces 124 of FIG. 1C.

While various examples of the present disclosure have been described above, it should be understood that they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the following claims and equivalents.

What is claimed is:

1. A semiconductor package, including:
a lead frame portion;
a semiconductor component electrically connected to the lead frame portion;
a raised connector including a vertical column and a horizontal pad contiguous with the vertical column, the raised connector having a continuous core extending throughout the vertical column and the horizontal pad, the continuous core being electrically conductive, the vertical column being attached to the lead frame portion; and
an encapsulation material contacting the lead frame portion and the raised connector, wherein the horizontal pad is exposed at a top surface of the encapsulation material.

2. The semiconductor package of claim 1, further including an external component over a top surface of the encapsulation material, the external component being electrically connected to the horizontal pad.

3. The semiconductor package of claim 1, wherein the raised connector has a textured surface contacting the encapsulation material.

4. The semiconductor package of claim 1, wherein the lead frame portion has an alignment structure where the vertical column is attached.

5. The semiconductor package of claim 1, wherein the raised connector includes a solderable material on the horizontal pad.

6. The semiconductor package of claim 1, wherein the raised connector includes a solderable material surrounding the continuous core.

7. The semiconductor package of claim 1, wherein:
the vertical column is a first vertical column;
the raised connector further includes a second vertical column;
the second vertical column is attached to the lead frame portion; and
the continuous core extends throughout the second vertical column.

8. The semiconductor package of claim 1, wherein:
the raised connector is a first raised connector;
the vertical column is a first vertical column;
the horizontal pad is a first horizontal pad;
the continuous core is a first continuous core; and
the semiconductor package further includes a second raised connector including a second vertical column and a second horizontal pad contiguous with the second vertical column, the second raised connector having a second continuous core extending throughout the second vertical column and the second horizontal pad; wherein:
the second vertical column is attached to the lead frame portion;
the second horizontal pad is exposed at the top surface of the encapsulation material; and
the encapsulation material contacts the second raised connector.

9. The semiconductor package of claim 1, wherein a pad thickness of the continuous core in the horizontal pad is greater than a bus thickness of the lead frame portion adjacent to the vertical column.

10. The semiconductor package of claim 1, wherein a column width of the continuous core in the vertical column is greater than a bus thickness of the lead frame portion adjacent to the vertical column.

11. A method of forming a semiconductor package, including:
attaching a semiconductor component to a lead frame portion;
providing a raised connector including a vertical column and a horizontal pad connected to the vertical column, the raised connector having a continuous core extending throughout the vertical column and the horizontal pad, the continuous core being electrically conductive;
attaching the vertical column to the lead frame portion; and
forming an encapsulation material on the lead frame portion and the raised connector, wherein the horizontal pad is exposed at a top surface of the encapsulation material.

12. The method of claim 11, wherein attaching the vertical column to the lead frame portion includes forming a solder connection between the vertical column and the lead frame portion.

13. The method of claim 11, wherein the raised connector has a textured surface contacting the encapsulation material.

14. The method of claim 11, wherein the lead frame portion has an alignment structure where the vertical column is attached.

15. The method of claim 11, wherein the raised connector include solder surrounding the continuous core.

16. The method of claim 11, further including attaching an external component over a top surface of the encapsulation material, and forming an electrical connection between the external component and the horizontal pad.

17. The method of claim 16, wherein forming the electrical connection between the external component and the horizontal pad includes forming a solder connection between the external component and the horizontal pad.

18. The method of claim 11, wherein a pad thickness of the continuous core in the horizontal pad is greater than a bus thickness of the lead frame portion adjacent to the vertical column.

19. The method of claim 11, wherein a column width of the continuous core in the vertical column is greater than a bus thickness of the lead frame portion adjacent to the vertical column.

20. The method of claim 11, wherein the lead frame portion is a first lead frame portion, and the raised connector is connected to a second lead frame portion, and further including separating the raised connector from the second lead frame portion after forming the encapsulation material on the lead frame portion and the raised connector.
